(19) United States
(12) Patent Application Publication
(10) Pub. No.: US 2024/0288904 A1
(43) Pub. Date: Aug. 29, 2024

(54) CONNECTION MECHANISM AND ELECTRONIC DEVICE

(71) Applicant: Lenovo (Beijing) Limited, Beijing (CN)

(72) Inventors: Ran ZHANG, Beijing (CN); Liang HAN, Beijing (CN); Guangming GUO, Beijing (CN)

(21) Appl. No.: 18/585,584

(22) Filed: Feb. 23, 2024

(30) Foreign Application Priority Data
Feb. 24, 2023 (CN) 202310182809.X

(51) Int. Cl. G06F 1/16; H05K 5/02

(52) U.S. Cl. CPC G06F 1/1654; G06F 1/1624; G06F 1/1679; H05K 5/0217

(57) ABSTRACT

A connection mechanism includes a first connection unit, a second connection unit, and a separation and locking control structure. The second connection unit is separated from and locked with the first connection unit in an insertion method. The separation and locking control structure includes a first control member and a second control member. The first control member is connected to the first connection unit to drive the first connection unit to move between a first position and a second position. The second control member abuts against the second connection unit when the second connection unit is inserted into the first connection unit. The first control member and the second control member have a first status and a second status.

### CROSS-REFERENCE TO RELATED APPLICATION

The present disclosure claims priority to Chinese Patent Application No. 202310182809.X, filed on Feb. 24, 2023, the entire content of which is incorporated herein by reference.

### TECHNICAL FIELD

The present disclosure relates to the electronic device technology field and, more particularly, to a connection mechanism and an electronic device.

### BACKGROUND

Electronic devices are widely used. For example, for a 2-in-1 notebook computer, a tablet apparatus and a keyboard apparatus are connected through a connection mechanism. Based on the connection mechanism, the tablet apparatus and the keyboard apparatus can be separated to satisfy a tablet mode and a notebook mode. For an existing 2-in-1 laptop computer, to realize the tablet mode, a button of the connection mechanism often needs to be pressed down while the tablet apparatus needs to be pulled off from the keyboard apparatus. The separation cannot be performed by a single hand.

### SUMMARY

An aspect of the present disclosure provides a connection mechanism, including a first connection unit, a second connection unit, and a separation and locking control structure. The second connection unit is separated from and locked with the first connection unit in an insertion method. The separation and locking control structure includes a first control member and a second control member. The first control member is connected to the first connection unit to drive the first connection unit to move between a first position and a second position. The second control member abuts against the second connection unit when the second connection unit is inserted into the first connection unit. The first control member and the second control member have a first status and a second status. In the first status, the first connection unit is kept at the first position to allow the second connection unit to be inserted relative to the first connection unit to be locked. In the second status, the first connection unit is kept at the second position to allow the second connection unit to be pulled out relative to the first connection unit to be in a separated status.

An aspect of the present disclosure provides an electronic device, including a first body, a second body, and a connection mechanism. The connection mechanism connects the first body and the second body to achieve a detachable connection between the first body and the second body. The connection mechanism includes a first connection unit, a second connection unit, and a separation and locking control structure. The second connection unit is separated from and locked with the first connection unit in an insertion method. The separation and locking control structure includes a first control member and a second control member. The first control member is connected to the first connection unit to drive the first connection unit to move between a first position and a second position. The second control member abuts against the second connection unit when the second connection unit is inserted into the first connection unit. The first control member and the second control member have a first status and a second status. In the first status, the first connection unit is kept at the first position to allow the second connection unit to be inserted relative to the first connection unit to be locked. In the second status, the first connection unit is kept at the second position to allow the second connection unit to be pulled out relative to the first connection unit to be in a separated status.

### BRIEF DESCRIPTION OF THE DRAWINGS

FIG. 1 illustrates a schematic structural diagram of an electronic device in two application modes according to some embodiments of the present disclosure.

FIG. 2 illustrates a schematic structural diagram of an electronic device (a first body and a second body being separated from each other) according to some embodiments of the present disclosure.

FIG. 3 illustrates a schematic structural diagram of a connection mechanism (viewing from a direction) according to some embodiments of the present disclosure.

FIG. 4 illustrates a schematic diagram showing a lock connection between a second connection unit and a first connection unit of FIG. 3.

FIG. 5 illustrates a schematic structural diagram of a connection mechanism (a first control member and a second control member being at a first status with each other) according to some embodiments of the present disclosure.

FIG. 6 illustrates a schematic internal structural diagram of the connection mechanism in a corresponding status of FIG. 5.

FIG. 7 illustrates a schematic structural diagram of a second guide assembly of the connection mechanism of FIG. 5.

FIG. 8 illustrates a schematic structural diagram of a connection mechanism (a first control member and a second control member being in a second status with each other) according to some embodiments of the present disclosure.

FIG. 9 illustrates a schematic internal structural diagram of the connection mechanism in a corresponding status of FIG. 8.

FIG. 10 illustrates a schematic structural diagram of a connection mechanism (a first control member and a second control member being in a third status with each other) according to some embodiments of the present disclosure.

FIG. 11 illustrates a schematic internal structural diagram of the connection mechanism in a corresponding status of FIG. 10.

### REFERENCE NUMERAL

| | | |
|---|---|---|
| 100 Connection mechanism | 110 First connection unit | 111 Fixed shell |
| 112 Ball | 113 Clip member | 114 Reset member |
| 120 Second connection unit | 130 Separation and locking | |
| | control structure | |
| 131 First control member | 1311 Hook | 132 Second control member |
| 1321 Tilted surface portion | 133 Elastic reset member | |
| 134 Unlocking button | 135 Linkage assembly | 1351 Rod |
| 1352 Connection mating structure | | 13521 Sliding groove |
| 13522 Convex column | 136 Elastic member | |
| 137 First guide assembly | 138 Second guide assembly | |
| 1381 First guide groove | 1382 Second guide groove | |
| 1383 Third guide groove | 200 First body | 300 Second body |

### DETAILED DESCRIPTION OF THE EMBODIMENTS

In the following description, details are provided to thoroughly understand the present disclosure. However, those skilled in the art can know that the following description only shows embodiments of the present disclosure exemplarily. The present disclosure can be implemented without one or more such details. In addition, to avoid confusion with the present disclosure, technical features known in the art are not described in detail.

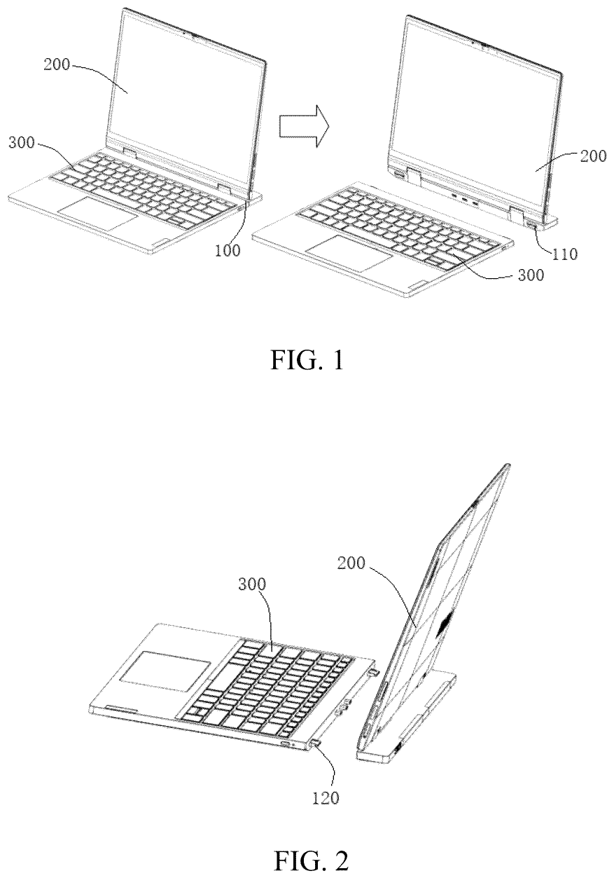

As shown in FIG. 1 and FIG. 2, an electronic device of embodiments of the present disclosure includes a first body 200, a second body 300, and a connection mechanism 100. The connection mechanism 100 connects the first body 200 and the second body 300 and is configured to realize a detachable connection between the first body 200 and the second body 300. Thus, the electronic device can have a first application mode and a second application mode. FIG. 1 shows the electronic device in the first application mode and the second application mode.

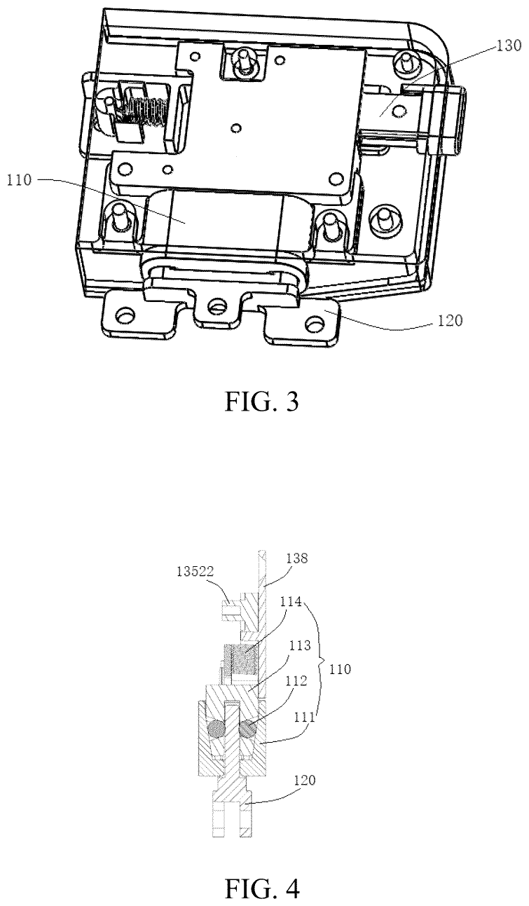

As shown in FIG. 1, FIG. 2, and FIG. 3, the connection mechanism 100 includes a first connection unit 110, a second connection unit 120, and a separation and locking control structure 130. The first connection unit 110 is arranged on the first body 200. The second connection unit 120 is arranged on the second body 300. Separation and locking connection between the second connection unit 120 and first connection unit 110 can be realized in an insertion method. As shown in FIG. 4, the insertion method for the second connection unit 120 and the first connection unit 110 is described below.

The first connection unit 110 includes a fixed shell 111, a ball 112, a clip member 113, and a reset member 114. The fixed shell 111 includes an insertion hole and an accommodation chamber inside the fixed shell 111. The accommodation chamber communicates with the outside through the insertion hole. The clip member 113 can move relative to the fixed shell 111. The clip member 113 includes two elastic clip portions arranged oppositely to each other. The two elastic clip portions extend into the accommodation chamber and have a gap therebetween. Each elastic portion includes a tilted surface mating member and an accommodation groove. The ball 112 is arranged in the accommodation groove. Based on the cooperation among the tilted surface mating member, the ball 112, and an inner wall of the fixed shell 111, a size of the gap between the two elastic clip portions can change when the clip member 113 moves relative to the fixed shell 111. The reset member 114 can be connected to the clip member 113 and configured to provide a restoring force after the clip member 113 moves relative to the fixed shell 111 to cause the clip member 113 to return to the initial position. The second connection unit 120 includes a sheet-shaped portion. The sheet-shaped portion can be inserted into the gap through the insertion hole. By moving the clip member 113, the gap between the two elastic clip portions can become smaller to realize the locking connection between the second connection unit 120 and the first connection unit 110. By moving the clip member 113, the gap between the two elastic clip portions can become larger to realize the separation between the second connection unit 120 and the first connection unit 110.

The clip member 113 can include a convex column 13522. The convex column 13522 can be moved to cause the clip member 113 to move.

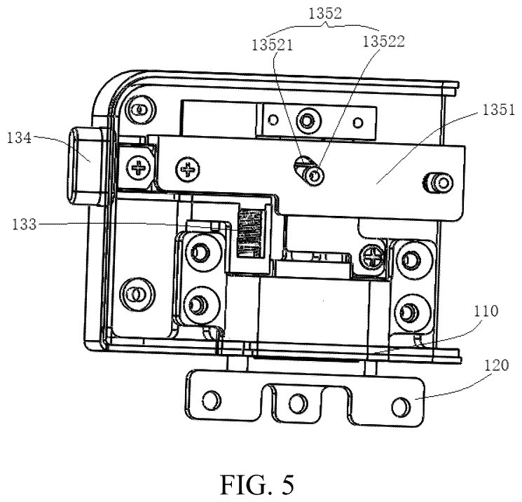

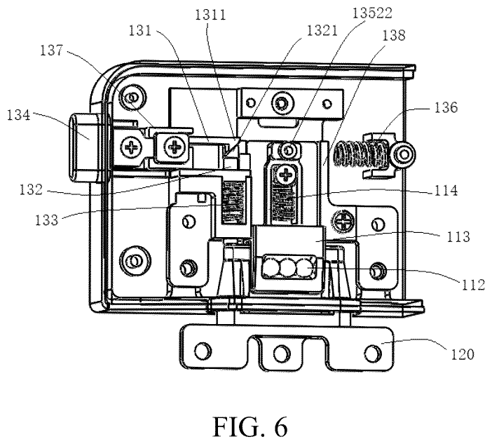

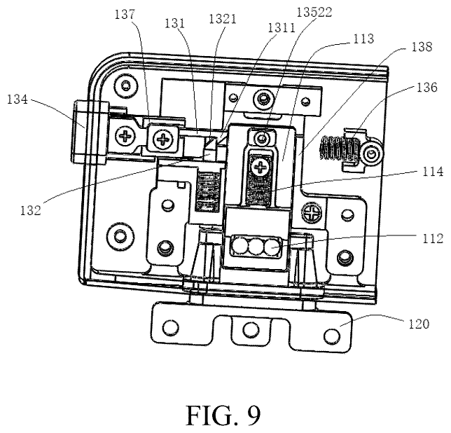

As shown in FIG. 3, FIG. 5, FIG. 6, FIG. 8, and FIG. 9, the separation and locking control structure 130 includes a first control member 131 and a second control member 132. The first control member 131 is connected to the first connection unit 110 to drive the first connection unit 110 to move between the first position and the second position. The second control member 132 abuts against the second connection unit 120 when the second connection unit 120 is inserted into the first connection unit 110. The first control member 131 and the second control member 132 have at least a first status (as shown in FIG. 6) and a second status (as shown in FIG. 9). In the first status, the first connection unit 110 can be kept at the first position to allow the second connection unit 120 to be inserted relative to the first connection unit 110 to be mutually locked and connected. The first position can correspond to a locking position. In the second status, the first connection unit 110 can be kept at the second position to allow the second connection unit 120 to be pulled out relative to the first connection unit 110 to be in a separated status. The second position can correspond to a separated position. When the first connection unit 110 includes the fixed shell 111, the ball 112, the clip member 113, and the reset member 114, the position of the fixed shell 111 can be fixed. The first connection unit 110 being movable between the first position and the second position can include the clip member 113 being movable between the first position and the second position. As shown in FIG. 5 and FIG. 6, the clip member 113 is at the first position. As shown in FIG. 8 and FIG. 9, the clip member 113 is at the second position.

In the connection mechanism 100, based on the configuration of the separation locking control structure 130, when the first connection unit 110 and the second connection unit 120 need to be separated, the first control member 131 and the second control member 132 can be caused to be in the second status as shown in FIG. 8 and FIG. 9 to keep the first connection unit 110 at the second position for unlocking. Then, the second connection unit 120 can be pulled out relative to the first connection unit 110 when the first connection unit 110 and the second connection unit 120 are unlocked. Thus, the first connection unit 110 and the second connection unit 120 can be separated by a single hand.

In some embodiments of the present disclosure, the electronic device can be a portable terminal device, such as a 2-in-one laptop. Correspondingly, the first body 200 can be a tablet apparatus, and the second body 300 can be a keyboard apparatus. The tablet apparatus can be detachably connected to the keyboard apparatus via the connection mechanism 100 to allow the electronic device to meet the requirements of a tablet mode and a laptop mode. After applying the connection mechanism 100 to a 2-in-one laptop, when the tablet apparatus needs to be separated from the keyboard apparatus to meet the requirement of the tablet mode, the first control member 131 and the second control member 132 can be in the second status with each other. The first connection unit 110 can be kept at the second position for unlocking. Then, the second connection unit 120 can be pulled out relative to the first connection unit 110 to separate the tablet apparatus and the keyboard apparatus when the first connection unit 110 and the second connection unit 120 are unlocked. Then, the separation operation can be completed by a single hand to facilitate the electronic device to satisfy the requirement of the tablet mode.

As shown in FIG. 5, FIG. 6, FIG. 8, and FIG. 9, in embodiments of the present disclosure, the first control member 131 includes a hook 1311, and the second control member 132 includes a tilted surface portion 1321. In the first status as shown in FIG. 6, the hook 1311 is slidely connected to the tilted surface portion 1321. In the second status as shown in FIG. 9, the hook 1311 is snapped with the tilted surface portion 1321 and stops the first connection unit 110 to keep the first connection unit 110 at the second position. The hook 1311 stopping the first connection unit 110 can mean the hook 1311 stopping the clip member 113 to limit the movement of the clip member 113 to keep the first connection unit 110 at the second position. Then, through the design of the hook 1311 and the tilted surface portion 1321, different statuses can be realized, and the first connection unit 110 can be kept at the unlocking position when the first connection unit 110 needs to be separated from the second connection unit 120.

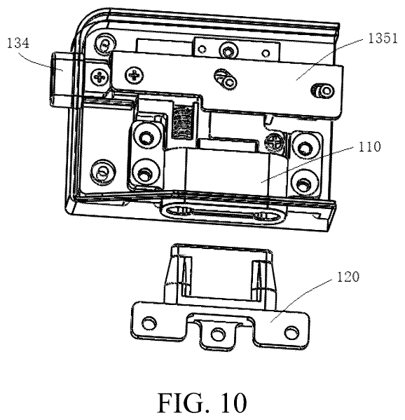

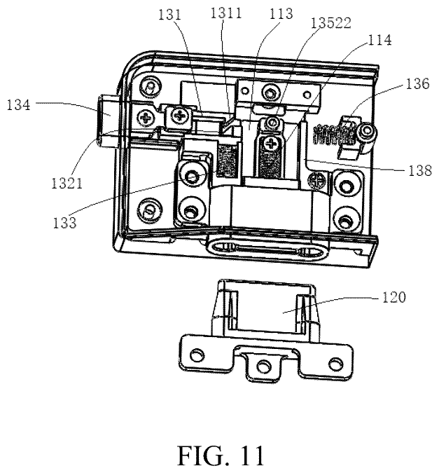

As shown in FIG. 10 and FIG. 11, the first control member 131 and the second control member 132 also have a third status. In the third status, the hook 1311 is disengaged from the tilted surface portion 1321. Then, by changing the status between the hook 1311 and the tilted surface portion 1321, the status between the first connection unit 110 and the second connection unit 120 can be changed.

The change in the status between the hook 1311 and the tilted surface portion 1321 can be achieved by moving the first control member 131 or the second control member 132. To move the second control member 132, during the process of inserting the second connection unit 120 into the insertion hole of the fixed shell 111 and after abutting the second connection unit 120 against the second control member 132, if the second connection unit 120 continues to be inserted, the second control member 132 can be pushed to move.

In embodiments of the present disclosure, to facilitate the resetting of the second control member 132, the second control member 132 can be connected to an elastic reset member 133. The elastic reset member 133 can be in a compressed status when the second connection unit 120 is mutually locked with the first connection unit 110. Thus, after the second connection unit 120 is pulled out relative to the first connection unit 110 to be in the separated status, the elastic reset member 133 can reset to push the second control member 132 to cause the first control member 131 to be in the third status relative to the second control member 132 as shown in FIG. 11.

Based on the above, the change in the status between the hook 1311 and the tilted surface portion 1321 can also be achieved by moving the first control member 131. To facilitate the movement of the first control member 131, in embodiments of the present disclosure, the separation and locking control structure 130 can further include an unlocking button 134 and a linkage assembly 135. The unlocking button 134 can be connected to the first control member 131 to switch the first control member 131 from the first status to the second status relative to the second control member 132. The first connection unit 110 can be connected to the first control member 131 through the linkage assembly 135. Thus, when the control member 131 is switched from the first status to the second status relative to the second control member 132, the first connection unit 110 can move from the first position to the second position. Thus, on one aspect, based on the unlocking button 134, the first control member 131 can move. On another aspect, based on the linkage assembly 135, when the unlocking button 134 is pressed, the first connection unit 110 can be moved simultaneously for unlocking.

In embodiments of the present disclosure, to achieve the linkage between the first connection unit 110 and the first control member 131, the linkage assembly 135 can include a rod 1351 and a connection mating structure 1352. The rod 1351 can be fixedly connected to the first control member 131, and the first connection unit can be connected to the rod 1351 through the connection mating structure 1352.

As shown in FIG. 5 and FIG. 6, to facilitate the unlocking button 134 to reset, the rod 1351 is connected to an elastic member 136. When the first control member 131 is in the second status relative to the second control member 132, the elastic member 136 can be in the compressed status. Thus, after the second connection unit 120 is pulled out relative to the first connection unit 110 to be in the separated status, the first control member 131 can be assisted to reset to the first status relative to the second control member 132.

In embodiments of the present disclosure, the connection mating structure 1352 can include a sliding groove 13521 formed at the rod 1351 and a convex column 13522 arranged at the first connection unit 110. In some embodiments, the convex column 13522 can be arranged at the clip member 113 of the first connection unit 110. Through the cooperation between the convex column 13522 and the sliding groove 13521, the first connection unit 110 can move along with the first control member 131 when the status of the first control member 131 is switched relative to the second control member 132.

In some embodiments, the connection mating structure 1352 can include the sliding groove 13521 formed at the first connection unit 110 and the convex column 13522 arranged at the rod 1351. In some embodiments, the sliding groove 13521 can be arranged at the clip member 113 of the first connection unit 110, and the first connection unit 110 can cooperate with the sliding groove 13521 through the convex column 13522. Thus, when the status of the first control member 131 is switched relative to the second control member 132, the first connection unit 110 can move with the first control member 131.

As shown in FIG. 6, the separation and locking control structure 130 further includes a first guide assembly 137 and a second guide assembly 138. The first guide assembly 137 can be configured to limit the first control ember 131 to move along the first direction (the first direction being a left-right direction in FIG. 6) when the status of the first control member 131 is switched relative to the second control member 132. The second guide assembly 138 can be configured to limit the second control member 132 to move along the second direction (the second direction being the up and down direction in FIG. 6) when the status of the first control member 131 is switched relative to the second control member 132. The first direction can be perpendicular to the second direction.

In some embodiments, a guide groove can be formed at the first guide assembly 137, and the first control member 131 can be limited to move along the guide groove.

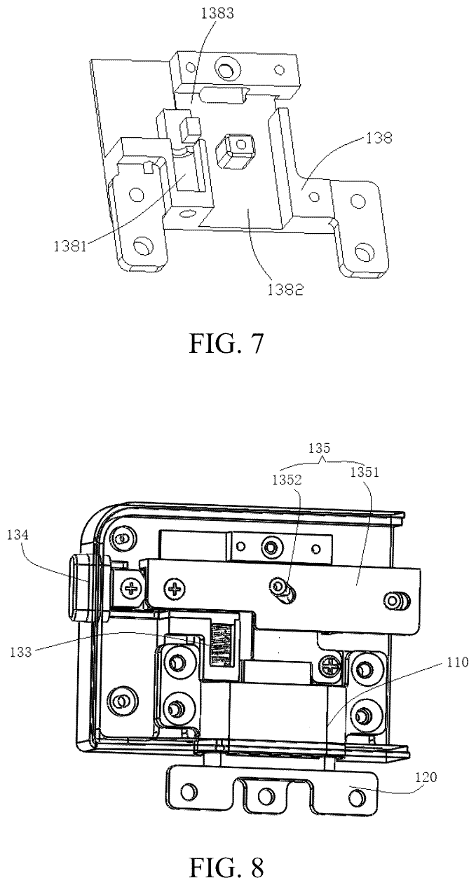

As shown in FIG. 6 and FIG. 7, the second guide assembly 138 includes a first guide groove 1381. The second control member 132 can be limited to move along the first guide groove 1381. The second guide assembly 138 further includes a second guide groove 1382. The clip member 113 can be limited to move along the second guide groove 1382 relative to the fixed shell 111. The second guide assembly further includes a third guide groove 1383. The rod 1351 can be limited to move along the third guide groove 1383.

The first guide assembly 137 and the second guide assembly 138 can be integrally formed or have a separate structure.

In embodiments of the present disclosure, the electronic device can include two connection mechanisms 100. The two connection mechanisms 100 can be arranged on a left side and a right side of the electronic device. The two connection mechanisms 100 can share a rod 1351 and an unlocking button 134. Thus, by pressing the unlock button 134, the two connection mechanisms 100 can be unlocked simultaneously.

The electronic device of the present disclosure may need to change an application mode. As shown in FIG. 1, when the 2-in-one laptop needs to switch from the laptop mode to the tablet mode, since the electronic device is in the laptop mode, the first control member 131 and the second control member 132 can be in the first status as shown in FIG. 5 and FIG. 6. The clip member 113 can be at the first position. Thus, the unlocking button 134 can be pressed down. The unlocking button 134 can drive the rod 1351 to move along the first direction and compress the elastic member 136. The rod 1351 can drive the clip member 113 to move upward to lift the clip member 113 to the second position as shown in FIG. 8 and FIG. 9. The hook 1311 of the first control member 131 can pass over the tilted surface member 1321 of the second control member 132. The first control member 131 and the second control member 132 can be in a second status. Thus, although the elastic member 136 is provided, the clip member 113 can be blocked by the hook 1311. Thus unlocking button cannot reset. The clip member 113 can be kept at the second position, i.e., at the unlocking position. Thus, the second connection unit 120 can be pulled out relative to the first connection unit 110. Thus, the tablet apparatus can be separated from the keyboard apparatus to realize the tablet mode.

As shown in FIG. 1, for the 2-in-one laptop, after the second connection unit 120 is pulled out relative to the first connection unit 110, a function force of the second connection unit 120 for the second control member 132. With the function of the elastic reset unit 110, the second control member 132 can be reset. The hook 1311 can be separated from the tilted surface 1321. The first control member 131 and the second control member 132 can be in the third status as shown in FIG. 11. With the function of the elastic member 136, the unlocking button 134 can return to the initial status. Under such a status, if the laptop mode is needed, the second connection unit 120 can be inserted into the insertion hole of the first connection unit 110. After the second connection unit 120 abuts against the second control member 132, if the second control member 120 continues to be inserted, the second control member 132 can be pushed to cause the first control member and the second control member 132 to be in the first status to realize the locked connection between the second connection unit 120 and the first connection unit 110.

In summary, the 2-in-one laptop can have the following advantages by adopting the connection mechanism 100 of embodiments of the present disclosure.
1. The structure is simple. The unlocking button 134 is pressed down first, and then the tablet apparatus is pulled out. Thus, the separation operation is completed by one hand.
2. After the tablet apparatus is inserted, the electronic device automatically resets.
3. The electrical control is not needed.

In some embodiments, the directions or position relationship indicated by the directional terms are generally based on the directions or position relationship shown in the accompanying drawings. To facilitate the description of the present disclosure and simplification of the description, when there is no contrary description, the directional terms do not indicate or imply that the indicated apparatuses or elements must have a specific orientation or be constructed or operated with a specific orientation. Thus, the directional terms cannot be considered to limit the scope of the present disclosure. The directional terms “inner” and “outer” can refer to the inner and outer relative to the contours of the members.

To facilitate the description, spatially relative terms such as “above,” “on” “on the upper surface,” and “over” are used to describe the spatial positional relationship of one or more members or features shown in the figures with respect to other members or features. The spatial relative terms can include the orientation described in the figures but also include different orientations in application or operation. For example, if the members in the drawings are inverted as a whole, the member being above or on other members or features can include the member being below or under the other members or structures. Thus, the exemplary term “on” can include two orientations such as above and below. In addition, the members or features can also be positioned with other different angles (e.g., rotating 90° or another angle). The present disclosure is intended to include all such situations.

The terms used here are only used to describe specific embodiments and are not intended to limit embodiments of the present disclosure. For example, the singular form used here, unless otherwise specified clearly, can be intended to include the plural form. In addition, the terms “include” and/or “contain” in the specification can indicate that features, steps, operations, members, assemblies, and/or a combination thereof can exist.

The terms “first” and “second” in the specification, the claims, and the accompanying drawings of the present disclosure are used to distinguish similar objects and are not necessarily used to describe a specific order or sequence. The terms used in this way can be interchangeable in appropriate situations. Thus, embodiments of the present disclosure can be implemented in an order other than the order shown or described here.

The present disclosure is described through the above embodiments. However, the above embodiments are provided for illustrative and explanatory purposes and are not intended to limit the scope of the present disclosure to the described embodiments. Furthermore, those skilled in the art can understand that the present disclosure is not limited to the above embodiments. According to the teachings of the present disclosure, various modifications and variations can be made, these modifications and variations are within the scope of the present disclosure. The scope of the present disclosure is subject to the claims and equivalent scope of the claims.

What is claimed is:

1. A connection mechanism comprising:
a first connection unit;
a second connection unit separated from and locked with the first connection unit in an insertion method; and
a separation and locking control structure including:
a first control member connected to the first connection unit to drive the first connection unit to move between a first position and a second position; and
a second control member abutting against the second connection unit when the second connection unit is inserted into the first connection unit;
wherein:
the first control member and the second control member have a first status and a second status;
in the first status, the first connection unit is kept at the first position to allow the second connection unit to be inserted relative to the first connection unit to be locked; and
in the second status, the first connection unit is kept at the second position to allow the second connection unit to be pulled out relative to the first connection unit to be in a separated status.

2. The connection mechanism according to claim 1, wherein:
the first control member includes a hook, and the second control member includes a tilted surface portion;
in the first status, the hook is slidably connected to the tilted surface portion; and
in the second status, the hook is engaged with the tilted surface portion, and the hook stops the first connection unit to keep the first connection unit at the second position.

3. The connection mechanism according to claim 2, wherein:
the first control member and the second control member also have a third status; and
in the third status, the hook is disengaged from the tilted surface portion.

4. The connection mechanism according to claim 3, wherein:
the second control member is connected to an elastic reset member; and
the elastic reset member is in a compressed status when the second connection unit is mutually locked with the first connection unit to reset to push the second control member after the second connection unit is pulled out relative to the first connection unit to the separated status to cause the first control member to be in the third status relative to the second control member.

5. The connection mechanism according to claim 1, wherein the separation and locking control structure further includes:
an unlocking button connected to the first control member and configured to switch the first control member from the first status to the second status relative to the second control member; and
a linkage assembly, the first connection unit being connected to the first control member through the linkage assembly, and the first connection unit moving from the first position to the second position when the first control member is switched from the first status to the second status relative to the second control member.

6. The connection mechanism according to claim 5, wherein the linkage assembly includes:
a rod fixedly connected to the first control member; and
a connection mating structure, the first connection unit is connected to the rod through the connection mating structure.

7. The connection mechanism according to claim 6, wherein:
the rod is connected to an elastic member; and
the elastic member is in a compressed status when the first control member is in the second status relative to the second control member to assist the first control member to reset to the first status relative to the second control member when the second connection unit is pulled out to the separated status relative to the first connection unit.

8. The connection mechanism according to claim 6, wherein the connection mating structure includes:
a sliding groove formed at the rod and a convex column arranged at the first connection unit; or
a sliding groove formed at the first connection unit or a convex column arranged at the rod;
wherein:
the first connection unit moves with the first control member through the cooperation between the convex column and the sliding groove when a status of the first control member is switched relative to the second control member.

9. The connection mechanism according to claim 1, the separation and locking control structure further includes:
a first guide assembly configured to limit the first control member to move along a first direction when a status of the first control member is switched relative to the second control member; and
a second guide assembly configured to limit the second control member to move along a second direction when the status of the first control member is switched relative to the second control member, the first direction being perpendicular to the second direction.

10. An electronic device comprising:
a first body,
a second body, and
a connection mechanism connecting the first body and the second body to achieve a detachable connection between the first body and the second body and comprising:
a first connection unit arranged at the first body;
a second connection unit arranged at the second body, the second connection unit being separated from and locked with the first connection unit in an insertion method; and
a separation and locking control structure including:
a first control member connected to the first connection unit to drive the first connection unit to move between a first position and a second position; and
a second control member abutting against the second connection unit when the second connection unit is inserted into the first connection unit;
wherein:
the first control member and the second control member have a first status and a second status;
in the first status, the first connection unit is kept at the first position to allow the second connection unit to be inserted relative to the first connection unit to be locked; and
in the second status, the first connection unit is kept at the second position to allow the second connection unit to be pulled out relative to the first connection unit to be in a separated status.

11. The device according to claim 10, wherein:
the first control member includes a hook, and the second control member includes a tilted surface portion;
in the first status, the hook is slidably connected to the tilted surface portion; and
in the second status, the hook is engaged with the tilted surface portion, and the hook stops the first connection unit to keep the first connection unit at the second position.

12. The device according to claim 11, wherein:
the first control member and the second control member also have a third status; and
in the third status, the hook is disengaged from the tilted surface portion.

13. The device according to claim 12, wherein:
the second control member is connected to an elastic reset member; and
the elastic reset member is in a compressed status when the second connection unit is mutually locked with the first connection unit to reset to push the second control member after the second connection unit is pulled out relative to the first connection unit to the separated status to cause the first control member to be in the third status relative to the second control member.

14. The device according to claim 10, wherein the separation and locking control structure further includes:
an unlocking button connected to the first control member and configured to switch the first control member from the first status to the second status relative to the second control member; and
a linkage assembly, the first connection unit being connected to the first control member through the linkage assembly, and the first connection unit moving from the first position to the second position when the first control member is switched from the first status to the second status relative to the second control member.

15. The device according to claim 14, wherein the linkage assembly includes:
a rod fixedly connected to the first control member; and
a connection mating structure, the first connection unit is connected to the rod through the connection mating structure.

16. The device according to claim 15, wherein:
the rod is connected to an elastic member; and
the elastic member is in a compressed status when the first control member is in the second status relative to the second control member to assist the first control member to reset to the first status relative to the second control member when the second connection unit is pulled out to the separated status relative to the first connection unit.

17. The device according to claim 15, wherein the connection mating structure includes:
a sliding groove formed at the rod and a convex column arranged at the first connection unit; or
a sliding groove formed at the first connection unit or a convex column arranged at the rod;
wherein:
the first connection unit moves with the first control member through the cooperation between the convex column and the sliding groove when a status of the first control member is switched relative to the second control member.

18. The device according to claim 10, the separation and locking control structure further includes:
a first guide assembly configured to limit the first control member to move along a first direction when a status of the first control member is switched relative to the second control member; and
a second guide assembly configured to limit the second control member to move along a second direction when the status of the first control member is switched relative to the second control member, the first direction being perpendicular to the second direction.
